(19) United States
(12) Patent Application Publication
(10) Pub. No.: US 2008/0084016 A1
(43) Pub. Date: Apr. 10, 2008

(54) Support jig for a chip product

(75) Inventor: Hirohiko Kubo, Kawasaki (JP)

Correspondence Address: KRATZ, QUINTOS & HANSON, LLP, 1420 K Street, N.W., Suite 400, WASHINGTON, DC, 20005, US

(73) Assignee: FUJITSU LIMITED, Kawasaki (JP)

(21) Appl. No.: 11/785,466

(22) Filed: Apr. 18, 2007

(30) Foreign Application Priority Data
Oct. 4, 2006 (JP) 2006-272940

(51) Int. Cl. H01L 21/02; B23Q 3/06

(52) U.S. Cl. 269/59; 29/25.01; 324/765; 174/542

(57) ABSTRACT

A support jig makes it possible to easily machine and/or test a small chip product such as a magnetic head slider using existing manufacturing equipment that processes a workpiece in the form of a wafer. The support jig includes a substrate formed in the shape of a flat plate, a slide plate that is set inside a setting concave portion provided in one surface of the substrate and moves between a locking position where a tested object is locked between the slide plate and an inner surface of the setting concave portion and a withdrawal position away from the locking position; and a holding means that holds the slide plate at the locking position.

### BACKGROUND OF THE INVENTION

1. Field of the Invention

The present invention relates to a support jig for a chip product used when carrying out testing, machining, or the like on a chip product, such as a magnetic head slider, that is in the form of a small chip.

2. Related Art

The manufacturing of a magnetic head slider includes a procedure that tests the characteristics of the magnetic head slider to implement quality control over products and/or carries out a process such as FIB (Focused Ion Beam etching) on the magnetic head slider and then observes the form of the electrodes formed on the magnetic head slider.

To carry out such tests, it is possible to provide a dedicated testing apparatus or processing apparatus to carry out the required machining or testing on individual magnetic head sliders. Doing so however incurs an increased equipment cost, and for this reason tested objects are currently machined and/or tested using the manufacturing equipment of an existing magnetic head slider or the like. Since such existing equipment carries out processes on workpieces in the form of wafers, when testing magnetic head sliders as tested objects, a support jig formed as a wafer is used and testing or the like is carried out with the test pieces supported on the supported jig.

FIGS. 7A and 7B show the conventional method used when carrying out the required machining and/or testing on a magnetic head slider 4 as a tested object that is supported by a support substrate 5 in the form of a wafer. Conventionally, the magnetic head slider 4 is tested after being attached to the support substrate 5 using an adhesive 6. The required tests and the like are carried out with one or a plurality of the magnetic head sliders 4 as tested objects being supported on the support substrate 5.
Patent Document 1

Japanese Laid-Open Utility Model No. H02-108331
Patent Document 2

Japanese Laid-Open Patent Publication No. H10-294346

### SUMMARY OF THE INVENTION

A process that implements quality control of products by testing the characteristics of a number of tested objects taken as a sample from the products is carried out frequently. Every time such process is carried out the tested objects (magnetic head sliders) have to be attached to and supported on support substrates 5 by a manual operation, which makes the process extremely complex. Also, since the tested objects are handled by attaching the tested objects to the support substrate 5, it is almost impossible to reuse the samples after testing. Since it is also impossible to reuse the support substrates 5, there is the problem of increased cost due to waste.

Products are tested by carrying out experiments with a testing device having been aligned with the tested objects supported on the support substrate 5. However, with a method where the tested objects are attached to the support substrates 5 by a manual operation, it is difficult to dispose the tested objects correctly at the predetermined position. Also, with a method where the tested objects are attached to the support substrates 5, since the tested objects will protrude from the surface of the support substrate 5 by the thickness of the objects, when using existing manufacturing equipment that operates on the condition that the positions and thicknesses of the workpieces are constant, it will be necessary to readjust the setting of the equipment to carry out the testing or required machining. This also results in the problem of reduced workability.

To solve the problems described above, it is an object of the present invention to provide a support jig for a chip product that enables tested objects to be easily attached to and detached from the support jig when testing or machining small chip products such as magnetic head sliders using existing manufacturing equipment that processes workpieces formed in the shape of a wafer. By doing so, the support jig improves the efficiency of machining and testing processes for the tested objects. Also, by making it possible to carry out the testing process reliably, the support jig can reduce the cost of implementing quality control of products.

To achieve the stated object, a support jig for a chip product according to the present invention includes: a substrate formed in the shape of a flat plate; a slide plate that is set inside a setting concave portion provided in one surface of the substrate and moves between a locking position where a tested object is locked between the slide plate and an inner surface of the setting concave portion and a withdrawal position away from the locking position; and a holding means that holds the slide plate at the locking position. Note that the overall shape of the support jig according to the present invention is formed as a thin flat plate in the same way as a ceramic wafer or a silicon wafer used when forming magnetic head sliders or silicon chips.

By forming the slide plate with a thickness that matches a depth of the setting concave portion, it is possible to form the entire support jig as a flat plate with the same thickness. This means that the tested object can be machined and/or tested using existing manufacturing equipment that carries out processing on a wafer.

Also, by forming the slide plate with a rectangular planar form, forming the setting concave portion with a rectangular planar form that encloses the slide plate, and supporting the tested object by pressing the tested object between a front edge of the setting concave portion and a front edge of the slide plate, it is possible to easily support one or a plurality of tested objects by having the objects held between the setting concave part and the slide plate.

The holding means may be a pressurizing spring that is mounted inside the surface of the substrate and presses the slide plate toward the locking position. By using a construction where the slide plate is pressed and energized by a pressurizing spring, it becomes easy to attach and detach the tested objects and by mounting the pressurizing spring inside the surface of the substrate, it is possible to form the entire support jig in the shape of a wafer.

By providing an engagement hole that engages a locking tab provided on the slide plate in the substrate, and providing the slide plate so as to move inside the setting concave portion between the locking position where the tested object is locked and the withdrawal position away from the locking position in a state where the locking tab has engaged the engagement hole, it becomes possible for the slide plate to slide reliably across the surface of the substrate, the slide plate is prevented from rising above the substrate, and the entire support jig can be kept in a wafer-like form.

By forming the substrate and the slide plate of a conductive material, it is possible to avoid the problem of the tested objects becoming damaged by static electricity.

With the support jig for a chip product according to the present invention, the support jig is formed in the shape of a flat wafer and it is possible to support a tested object by allowing the slide plate to move within the setting concave part, which makes it extremely easy to carry out operations that set and remove the tested objects on the support jig. Since the support jig can be formed so that the entire support jig is in the shape of a wafer even when the tested objects have been mounted on the support jig, processes such as machining on the tested objects and testing of the tested objects can be carried out easily using existing manufacturing equipment that carries out processing on a wafer as a workpiece.

### BRIEF DESCRIPTION OF THE DRAWINGS

The aforementioned and other objects and advantages of the present invention will become apparent to those skilled in the art upon reading and understanding the following detailed description with reference to the accompanying drawings.

In the drawings:

FIG. 1 is an exploded perspective view of a support jig for a chip product;

FIG. 2 is a perspective view of the support jig for a chip product;

FIGS. 3A and 3B are perspective views showing the support jig for a chip product when looking at the rear surface;

FIG. 4 is a perspective view of the support jig that has been cut along a line that passes through an engagement hole;

FIG. 5 is a perspective view of the support jig that has been cut along a line that passes through the support jig in the front-rear direction;

FIG. 6 is a perspective view showing how magnetic head sliders are attached to the support jig for a chip product; and

FIGS. 7A and 7B are perspective views showing a conventional method where machining or the like is carried out with a magnetic head slider supported on a support substrate.

### DESCRIPTION OF THE PREFERRED EMBODIMENTS

Preferred embodiments of a support jig for a chip product according to the present invention will now be described in detail with reference to the attached drawings.

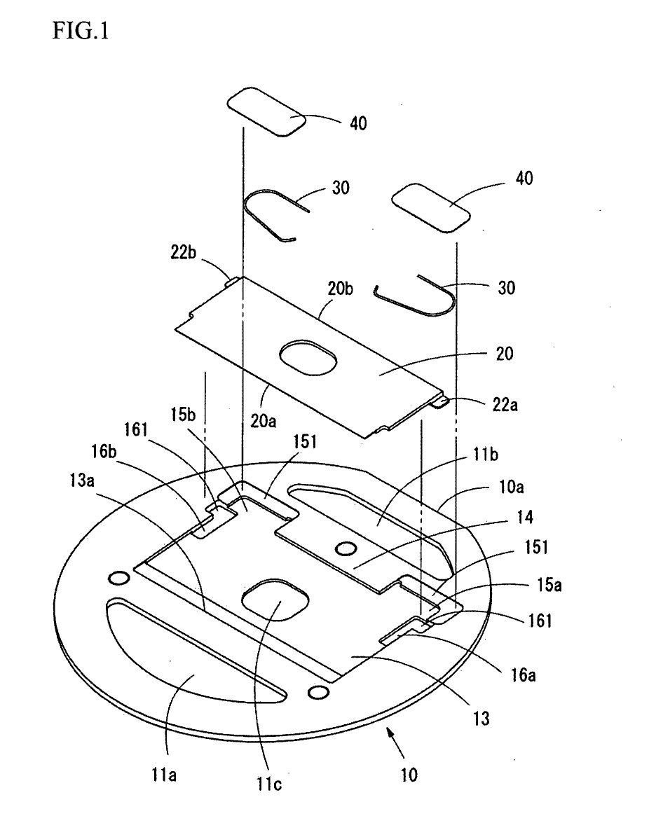

FIG. 1 is an exploded perspective view showing the construction of an embodiment of a support jig for a chip product. The support jig for a chip product includes a substrate 10 formed in the shape of a disc and a slide plate 20 that is attached to one surface of the substrate 10 so as to slide parallel to the surface of the substrate 10.

The slide plate 20 can move between a locking position where a tested object is locked on the substrate 10 and a release position away from the locking position. In the present embodiment, the support jig includes pressurizing springs 30 as a holding means for causing the slide plate 20 to hold the tested object at the locking position.

The substrate 10 is formed as a flat plate with the same shape as a wafer used in a manufacturing apparatus. In the present embodiment, the substrate 10 is formed of stainless steel with a thickness of 2 mm. Stainless steel is used as the substrate 10 to achieve a predetermined strength for the substrate 10 and to form the substrate 10 as a conductive member that does not become electrically charged since the tested objects may be tested using an electron microscope. It should be obvious that depending on how the support jig is used, metal materials aside from stainless steel can be used for the substrate 10, and in some cases it is also possible to use a non-conductive material.

A setting concave portion 13 for disposing the slide plate 20 is provided in the center of one surface of the substrate 10. The setting concave portion 13 is formed with a rectangular planar form in accordance with the shape of the slide plate 20 that also has a rectangular planar form. In the present embodiment, the setting concave portion 13 is formed so that the longitudinal direction of the setting concave portion 13 is parallel with an orientation flat portion 10a provided on the substrate 10.

The tested object is supported by being sandwiched from the front and rear between an inner surface of a front edge 20a of the slide plate 20 and an inner surface of a front edge 13a of the setting concave portion 13. The setting concave portion 13 is produced with a suitable length in the front-rear direction to provide sufficient space for disposing the tested object and to allow the slide plate 20 to move in the front-rear direction inside the setting concave portion 13. Note that both side surfaces in the length direction of the setting concave portion 13 act as guide surfaces when the slide plate 20 slides in the front-rear direction.

The depth of the setting concave portion 13 and the thickness of the slide plate 20 are set so that when the slide plate 20 has been set in the setting concave portion 13, the upper surface of the substrate 10 and the upper surface of the slide plate 20 have a uniform height. Although the thickness of the slide plate 20 is set at 1 mm and the depth of the setting concave portion 13 is set at 1 mm in the present embodiment, the thickness of the slide plate 20 and the depth of the setting concave portion 13 can be set as appropriate. The thickness of the slide plate 20 should also preferably be set approximately equal to the thickness of the tested object set on the support jig.

Openings 11a, 11b, and 11c are formed in front of and behind the setting concave portion 13 and in the center of the setting concave portion 13. When the support jig is manufactured using stainless steel, the support jig will be heavy compared to a ceramic wafer and a silicon wafer of the same thickness and the same shape. By forming the openings 11a, 11b, and 11c, the weight of the support jig can be reduced, thereby making the support jig easier to handle. However, when a tested object is supported on the substrate 10 and the required machining and testing are carried out on the sample, it is necessary to avoid deformation of the substrate 10, such as warping. Accordingly, the sizes and formation positions of the openings 11a, 11b, and 11c need to be set so that the substrate 10 does not deform.

A convex edge portion 14 that has the same height as the upper surface of the substrate 10 is provided at a rear side edge of the setting concave portion 13. Spring setting portions 15a and 15b on which the pressurizing springs 30 are set are provided on both sides of the convex edge portion 14. The spring setting portions 15a and 15b are formed so that the height from the bottom surface of the setting concave portion 13 is equal to or slightly larger than the diameter of the spring material used for the pressurizing springs 30 and so that the spring setting portions 15a and 15b are formed slightly lower than the outer surface of the substrate 10.

Engagement holes 16a and 16b that allow the slide plate 20 to move forward and backward in a state where the slide plate 20 engages the substrate 10 are provided at the rear of both side edges in the longitudinal direction of the setting concave portion 13.

The engagement holes 16a and 16b are formed with planar forms that extend lengthwise in the front-rear direction of the substrate 10 and have rear portions that protrude somewhat outward to the sides of the substrate 10.

The slide plate 20 is formed of stainless steel in the same way as the substrate 10 and as described earlier is formed with a rectangular planar form. Locking tabs 22a and 22b that engage the engagement holes 16a and 16b are provided at the rear end on both sides in the longitudinal direction of the slide plate 20. The locking tabs 22a and 22b are formed so as to protrude outward from the side edges of the slide plate 20 at a lower position than the upper surface of the slide plate 20, and are formed with a planar form that can be inserted from above into the wide portions 161 that are part of the engagement holes 16a and 16b. The side surface of the front edge 20a of the slide plate 20 is formed so as to be tapered with the upper part protruding forward.

The pressurizing springs 30 are bent so as to have U-shaped planar forms and front end portions of the pressurizing springs 30 on the side that contacts a rear edge 20b of the slide plate 20 are formed so as to be somewhat bent back toward the inside.

Seal plates 40 are formed with a suitable shape and thickness to fit into stepped concave portions 151 that are formed by the upper surfaces of the spring setting portions 15a and 15b and the upper surface of the substrate 10.

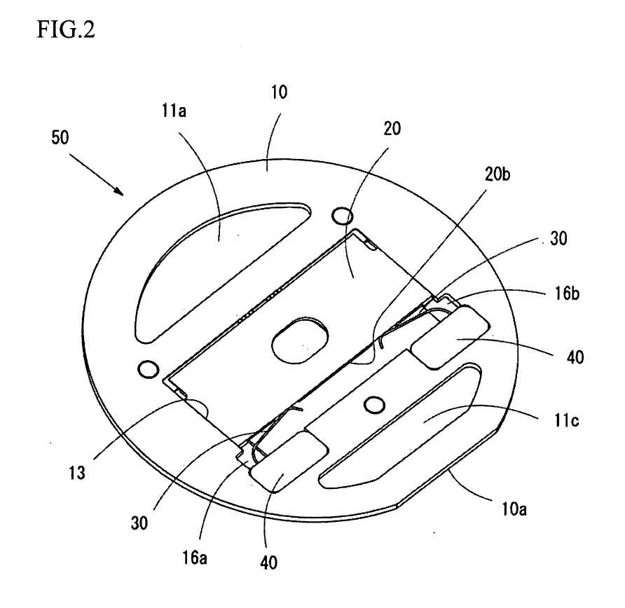

FIG. 2 is a perspective view showing how the slide plate 20, the pressurizing springs 30, and the seal plates 40 are attached to the substrate 10 to construct a support jig 50. The slide plate 20 is set in the setting concave portion 13 provided on the substrate 10, the pressurizing springs 30 are attached so as to apply pressure between the rear edge 20b of the slide plate 20 and the side surfaces of the spring setting portions 15a and 15b, and the seal plates 40 are attached to the stepped concave portions 151. When the slide plate 20 is set in the setting concave portion 13, the locking tabs 22a and 22b are aligned with the engagement holes 16a and 16b and the slide plate 20 is set so as to slide forward. By doing so, the support jig 50 is formed in the overall shape of a flat plate like a wafer.

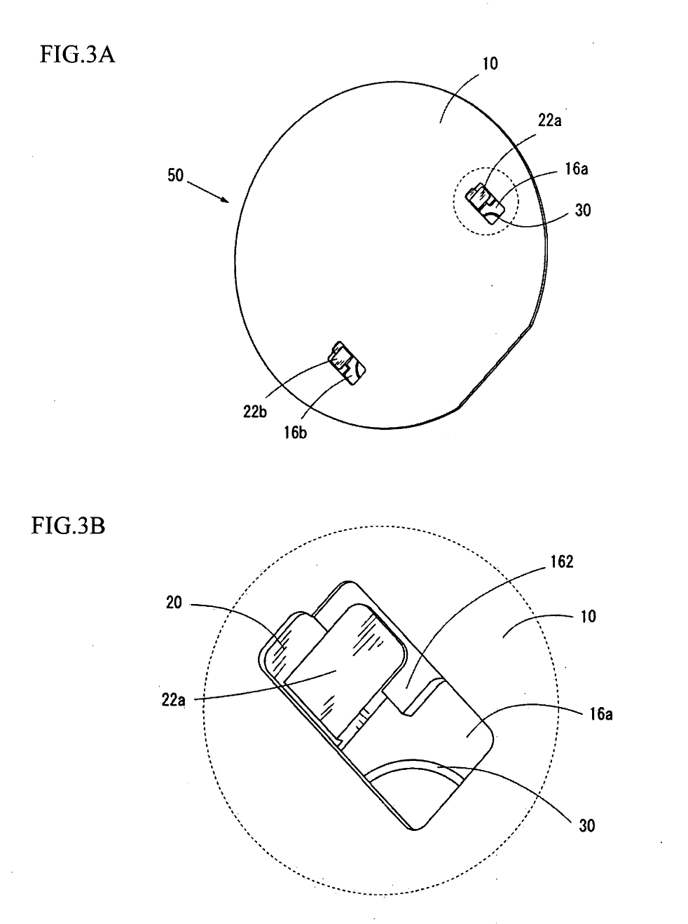

FIGS. 3A and 3B show the assembled support jig 50 when looking at the rear surface. FIG. 3A shows the state where the locking tabs 22a and 22b provided on the slide plate 20 have been fitted into the engagement holes 16a and 16b provided in the substrate 10. FIG. 3B is an enlargement of the construction of the engagement holes 16a and 16b and the locking tabs 22a and 22b.

Engagement tabs 162 extend outward from inner surfaces of the engagement holes 16a and 16b. The engagement tabs 162 extend from the inner surface of the setting concave portion 13, are formed thinner than the thickness of the substrate 10, and the rear surface sides of the engagement tabs 162 are formed as stepped portions.

The locking tabs 22a and 22b are formed with suitable heights and thicknesses so that when the locking tabs 22a and 22b have been inserted into the wide portions 161 of the engagement holes 16a and 16b, the locking tabs 22a and 22b can fit under the lower surfaces (i.e., the surfaces of the stepped portions) of the engagement tabs 162. By allowing the slide plate 20 to move forward, the locking tabs 22a and 22b are inserted under the lower surfaces of the engagement tabs 162. FIG. 3B shows a state where the locking tabs 22a and 22b have been inserted under the lower surfaces of the engagement tabs 162.

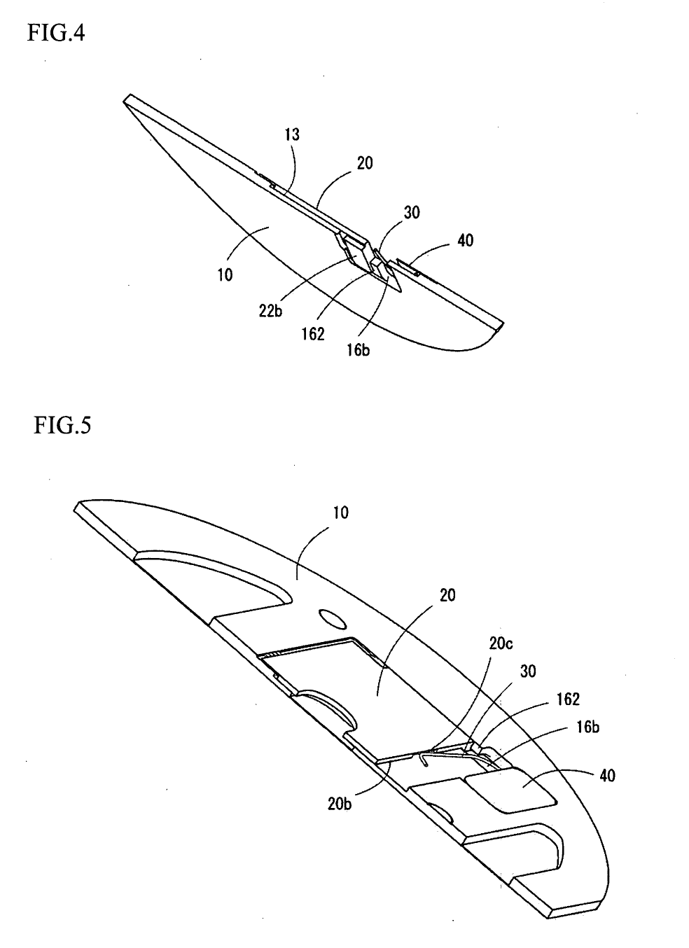

FIG. 4 is a perspective view of a state where the support jig 50 has been cut along a line that passes through the engagement hole 16b. FIG. 4 shows a state where the slide plate 20 has been set so as to make surface contact with the bottom surface of the setting concave portion 13 and the locking tab 22b has been inserted below the engagement tab 162 so as to engage the bottom of the engagement tab 162.

FIG. 5 is a perspective view of the support jig 50 in a state where the support jig 50 has been cut along a line that passes the center of the slide plate 20. FIG. 5 shows how a part of the side surface of the rear edge 20b of the slide plate 20 that makes contact with the end portion of the pressurizing spring 30 is formed as a tapered contact portion 22c so that the slide plate 20 is energized forward by the pressurizing spring 30. The locking tab 22b that has engaged the engagement hole 16b is inserted below the engagement tab 162.

In this way, the slide plate 20 is energized forward in a state where the locking tabs 22a and 22b have engaged the engagement holes 16a and 16b to set the slide plate 20 in the setting concave portion 13. By sliding in a state where the locking tabs 22a and 22b engage the engagement holes 16a and 16b, the slide plate 20 can be prevented from rising above the substrate 10 when the slide plate 20 moves and the slide plate 20 can be prevented from rising when a tested object has been set on the support jig 50. The seal plates 40 cover the base ends of the pressurizing springs 30 and act so as to hold the pressurizing springs 30 so that the pressurizing springs 30 do not become displaced from their attachment positions.

### Using the Support Jig

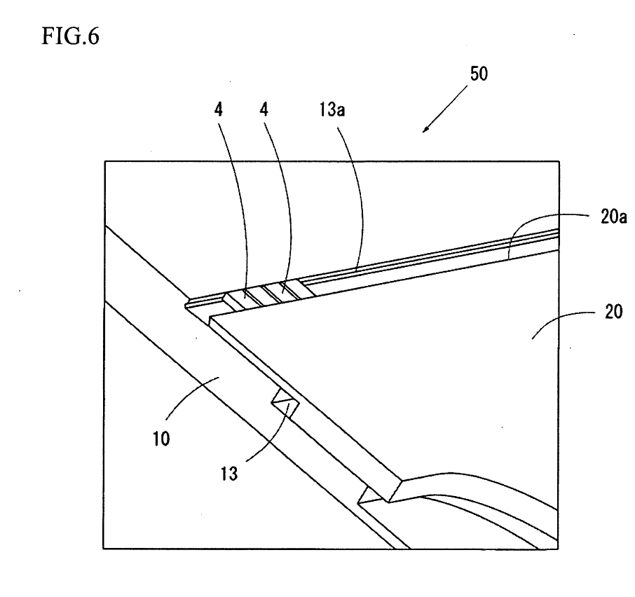

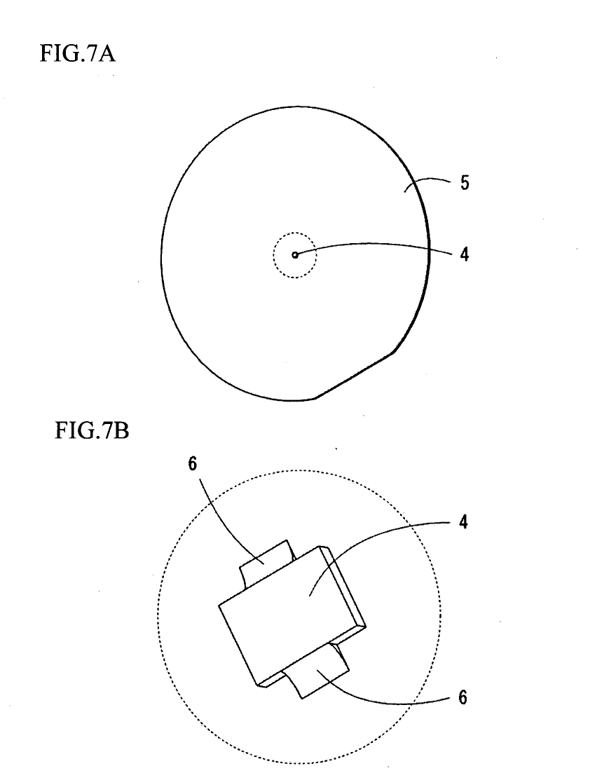

FIG. 6 shows an example of when the required machining or testing is carried out with magnetic head sliders attached as tested objects to the support jig 50 described earlier. When setting the magnetic head sliders 4 on the support jig 50, the slide plate 20 should be allowed to slide forward so that the magnetic head sliders 4 are sandwiched between the front edge 13a of the setting concave portion 13 and the front edge 20a of the slide plate 20. The magnetic head sliders 4 are therefore held and supported by the elastic force of the pressurizing springs 30. By forming the inner surface of the front edge 13a of the setting concave portion 13 as a tapered surface where the upper portion protrudes outward, the magnetic head sliders 4 are supported while being pressed toward the bottom surface of the setting concave portion 13.

As described earlier, by setting the depth of the setting concave portion 13 and the thickness of the slide plate 20 equal to the thickness of the magnetic head sliders 4, the upper surfaces of the magnetic head sliders 4 will be flush with the upper surface of the substrate 10.

The support jig for a chip product according to the present invention is characterized by disposing the various substrates such as the slide plate 20 inside one surface of the substrate 10 and within the thickness of the substrate 10 so that the entire support jig 50 is formed as a flat plate with uniform thickness in the same way as a wafer. Also, by attaching the magnetic head sliders 4 between edges of the setting concave portion 13 and the slide plate 20 it is possible for the entire support jig to have the same form as a wafer in the form of a flat plate even after the magnetic head sliders 4 have been attached. By doing so, it becomes possible to reliably carry out the required machining and testing on the magnetic head sliders 4 while using existing manufacturing equipment that carries out processing on a wafer.

By using a construction where the magnetic head sliders 4 are supported by being sandwiched inside the setting concave portion 13 by the slide plate 20, the operation of setting the magnetic head sliders 4 on the support jig 50 is easy, with it also being easy to detach the magnetic head sliders 4 after testing.

When handling extremely small products like the magnetic head sliders 4, a method that can set the products by sandwiching the products using the slide plate 20 without using adhesive is extremely beneficial in improving workability.

Also, since the magnetic head sliders 4 are not attached to a support substrate using adhesive, it is possible to reuse the magnetic head sliders 4 after testing. Since the support jig 50 is also reusable, the conventional problem of the support substrate 5 also going to waste is also avoided.

If the support jig 50 is manufactured using a conductive material such as stainless steel, it will be possible to prevent the magnetic head sliders from becoming charged even when testing is carried out using an electron microscope.

Also, by setting the mounting position of the magnetic head sliders 4 on the support jig 50 such as by setting the disposed positions of the setting concave portion 13 and the slide plate 20 in accordance with the orientation flat portion 10a of the substrate 10 as in the embodiment described above, it is possible to facilitate an operation that aligns a testing device or machining device with the magnetic head sliders.

Note that although an example where machining, testing or the like is carried out with magnetic head sliders 4 mounted on the support jig 50 has been described above, the support jig according to the present invention is not limited to being used to support magnetic head sliders and can be widely used when carrying out machining, testing, and the like on a chip product using manufacturing equipment that carries out machining or testing on a wafer. When doing so, the shape of the support jig should be designed so as to match the shape of the wafer being handled by the manufacturing equipment used to manufacture the chip product.

What is claimed is:

1. A support jig for a chip product comprising:
a substrate formed in the shape of a flat plate;
a slide plate that is set inside a setting concave portion provided in one surface of the substrate and moves between a locking position where a tested object is locked between the slide plate and an inner surface of the setting concave portion and a withdrawal position away from the locking position; and
a holding means that holds the slide plate at the locking position.

2. A support jig for a chip product according to claim 1, wherein the slide plate is formed with a thickness that matches a depth of the setting concave portion.

3. A support jig for a chip product according to claim 1,
wherein the slide plate is formed with a rectangular planar form,
the setting concave portion is formed with a rectangular planar form that encloses the slide plate, and
the tested object is supported by being pressed between a front edge of the setting concave portion and a front edge of the slide plate.

4. A support jig for a chip product according to claim 1
wherein the holding means is a pressurizing spring that is mounted inside the surface of the substrate and presses the slide plate toward the locking position.

5. A support jig for a chip product according to claim 1,
wherein an engagement hole that engages a locking tab provided on the slide plate is formed in the substrate, and
the slide plate is provided so as to move inside the setting concave portion between the locking position where the tested object is locked and the withdrawal position away from the locking position in a state where the locking tab has engaged the engagement hole.

6. A support jig for a chip product according to claim 1,
wherein the substrate and the slide plate are formed of a conductive material.
